(19) United States
(12) Patent Application Publication
(10) Pub. No.: US 2025/0300606 A1
(43) Pub. Date: Sep. 25, 2025

(54) Diode-Based Protection Circuit

(71) Applicant: pSemi Corporation, San Diego, CA (US)

(72) Inventors: Ymmen Goel, Austin, TX (US); James Francis McElwee, Austin, TX (US)

(21) Appl. No.: 18/612,392

(22) Filed: Mar. 21, 2024

(51) Int. Cl. H03F 1/52

(52) U.S. Cl. CPC H03F 1/523; H03F 2200/294; H03F 2200/441; H03F 2200/444

(57) ABSTRACT

Circuits and methods for providing a protection circuit that provides improved protection of DC-biased IC terminals, particularly for LNAs lacking a DC blocking input capacitor. Novel circuitry provides circuit protection against large signals and is comparable in performance to an anti-parallel diode voltage clamp for a non-DC biased IC input. The novel protection circuitry makes use of a series-diode protection circuit but adds a two-state circuit. For small signals at an IC terminal, the two-state circuit keeps the series diodes of the series-diode protection circuit reverse-biased. However, for high voltage swings at an IC terminal, the two-state circuit couples the inputs to the series-diode protection circuit so that the diodes behave like anti-parallel diodes, despite the presence of a DC bias on the IC input. The added two-state circuit has a minimal impact on circuit performance (e.g., noise-figure or gain for an LNA).

### BACKGROUND

### (1) Technical Field

The invention relates to electronic circuits, and more particularly to protection circuitry for electronic circuits.

### (2) Background

Many modern electronic systems include radio frequency (RF) receivers; examples include cellular telephones, personal computers, tablet computers, wireless network components, televisions, cable system “set top” boxes, and radar systems. Many RF receivers are paired with RF transmitters in the form of transceivers, which often are quite complex two-way radios. Amplifiers are a common component in RF transmitters, receivers, and transceivers, and are frequently used for power amplification of transmitted RF signals and for low-noise amplification of received RF signals.

Receiving an RF signal in many environments requires a high quality low-noise amplifier (LNA) as part of an RF “front end” (RFFE) receiver or transceiver chain of circuits. FIG. 1 is a simplified schematic diagram of a first example prior art LNA circuit 100. In the illustrated example, the LNA circuit 100 includes an amplifier core 102 comprising a stack of two series-connected field-effect transistors (FETs): a common-source FET M_{CS} and a common-gate FET M_{CG} coupled in a cascode arrangement. An optional FET stack 104 may be coupled to the drain of the M_{CG} FET to withstand high voltages. An RF input signal applied to an RF input terminal RF_{IN} is coupled through an impedance matching inductor L_{IN} and a DC blocking capacitor C_{IN} to the control gate of the common-source FET M_{CS}, which may be regarded as an input port INT of the amplification core 102.

The source of the common-source FET M_{CS} may be regarded as a degeneration port DT of the amplification core 102. A degeneration inductor L_{DG} is coupled between the degeneration port DT of the amplification core 102 and a reference potential, such as circuit ground.

The source of the common-gate FET M_{CG} is connected to the drain of the common-source FET M_{CS}. The drain of the common-gate FET M_{CG} provides an amplified RF output signal (directly or through the optional FET stack 104) at what may be regarded as an amplified-signal port AST of the amplification core 102. A CG Bias Generator circuit 106 may be included to provide a suitable bias voltage CG_V_{BIAS} to the common-gate FET M_{CG} and a CS Bias Generator circuit 108 may be included to provide a suitable bias voltage CS_V_{BIAS} to the common-source FET M_{CS}. In some embodiments, a single bias circuit may provide the bias voltages CG_V_{BIAS} and CS_V_{BIAS}.

In the illustrated example, the amplified-signal port AST is coupled to a voltage source terminal V_{DD} through a load module 110. In the illustrated example, the load module 110 includes a load inductor L_{LD} coupled in parallel with a de-queuing resistor R_{DQ}. The amplified-signal port AST is also coupled to an RF output terminal RF_{OUT} through a DC-blocking output capacitor C_{OUT}. The RF output terminal RF_{OUT} would typically be coupled to a 50-ohm load for many modern RF circuits.

Most or all of the components shown in FIG. 1 would be fabricated as part of an integrated circuit (IC). Providing protection against high-voltage voltage swings at the inputs of an IC, particularly an IC that includes LNA circuitry, significantly improves the “ruggedness” of the IC. For an LNA, such voltage swings generally comprise very high RF signal levels that may have a duration of seconds to minutes. Without protection, high-voltage voltage swings at an input of an IC may cause damage to FETs within the IC (e.g., gate-oxide breakdown and/or hot carrier injection).

In the example illustrated in FIG. 1, a voltage clamp 112 is coupled between a reference potential (e.g., circuit ground) and a node X located between the impedance matching inductor L_{IN} and the DC blocking capacitor C_{IN}. The example voltage clamp 112 comprises anti-parallel coupled diodes D1 and D2 that increase IC ruggedness by effectively clamping voltage swing at the input terminal RF_{IN}. Anti-parallel diodes may be used in the circuit of FIG. 1 because the LNA input is biased at 0V (i.e., no DC bias).

Referring to FIG. 1, the presence of the DC blocking capacitor C_{IN} ensures that the DC voltage at the RF input terminal RF_{IN} is zero. However, in capless LNAs, the absence of the DC blocking capacitor C_{IN} means that the input port INT of the amplification core is DC coupled to the input terminal of the LNA, and accordingly the DC voltage at RF_{IN} is not zero. An anti-parallel diode voltage clamp 112 of the type shown in FIG. 1 is generally not suitable if the input terminal RF_{IN} is DC-biased, as the DC bias will turn the voltage clamp 112 ON during small signal operation and shunt all DC and RF signals to circuit ground.

FIG. 2 is a simplified schematic diagram of a second example prior art LNA circuit 200. Similar in many aspects to the LNA 100 of FIG. 1, the LNA circuit 200 has two notable differences: first, the DC blocking capacitor C_{IN} is absent (indicated by the dashed oval 202); and second, a series-diode protection circuit 204 is coupled between a node X located between the impedance matching inductor L_{IN} and the input port INT of the amplification core 102 and both the voltage source terminal V_{DD} and a reference potential (e.g., circuit ground). The illustrated series-diode protection circuit 204 is shown as comprising a first diode D1 having its anode coupled to node X and its cathode coupled to the voltage source terminal V_{DD}, and a second diode D2 having its anode coupled to the reference potential and its cathode coupled to node X. The series-diode protection circuit 204 will start conducting through diode D1 when diode D1 is forward biased or start conducting through diode D2 when diode D2 is forward biased. A Schottky diode or a fast-switching diode is generally chosen for the diodes D1 and D2. However, the series-diode protection circuit 204 does not clamp the input voltage as well as anti-parallel diodes biased at 0V, particularly for large signals.

Accordingly, there is a need for a protection circuit that provides better protection of DC-biased IC inputs. The present invention addresses this need, particularly for LNAs.

### SUMMARY

The present invention encompasses circuits and methods for providing a protection circuit that provides improved protection of DC-biased IC terminals, particularly for LNAs lacking a DC blocking input capacitor (“capless LNAs”). Novel circuitry provides circuit protection against large signals and is comparable in performance to an anti-parallel diode voltage clamp for a non-DC biased IC input.

More particularly, the novel protection circuitry makes use of a series-diode protection circuit but adds a two-state circuit. For small signals at an IC terminal, the two-state circuit keeps the series diodes of the series-diode protection circuit reverse-biased. However, for high voltage swings at an IC terminal, the two-state circuit couples the inputs to the series-diode protection circuit so that the diodes behave like anti-parallel diodes despite the presence of a DC bias on the IC input. The added two-state circuit has a minimal impact on circuit performance (e.g., noise-figure or gain for an LNA).

One embodiment includes a protection circuit configured to be coupled to a circuit terminal and including a two-state circuit configured to be coupled to the circuit terminal, a voltage source, and a reference potential, the two-state circuit including a first node selectably couplable to the voltage source or to the reference potential; and a series-diode protection circuit configured to be coupled to the circuit terminal, the reference potential, and the first node of the two-state circuit.

One method for protecting a circuit terminal includes coupling an anode of a first diode to the circuit terminal; coupling an anode of a second diode to a reference potential and coupling a cathode of the second diode to the circuit terminal; and selectively coupling a cathode of the first diode to the reference potential when a large voltage signal is present on the circuit terminal, and otherwise coupling the cathode of the first diode to a voltage source

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1 is a simplified schematic diagram of a first example prior art LNA circuit.

FIG. 2 is a simplified schematic diagram of a second example prior art LNA circuit.

FIG. 3 is a simplified schematic diagram of an example LNA circuit with improved protection circuitry in accordance with the present invention.

FIGS. 4-6 are graphs of voltages versus time for the V_{GS}, V_{GD}, and V_{DS} parameters, respectively, of the common-source FET M_{CS} of an LNA during a large signal event, for three different protection circuits.

FIG. 7 is a top plan view of a substrate that may be, for example, a printed circuit board or chip module substrate (e.g., a thin-film tile).

FIG. 8 illustrates a prior art wireless communication environment comprising different wireless communication systems, and which may include one or more mobile wireless devices.

FIG. 9 is a block diagram of a transceiver that might be used in a wireless device, such as a cellular telephone, and which may beneficially incorporate an embodiment of the present invention for improved performance.

FIG. 10 is a process flow chart showing one method for protecting a plurality of low-noise amplifiers, fabricated as part of an integrated circuity that includes a voltage source pin, from electro-static discharge events.

Like reference numbers and designations in the various drawings indicate like elements unless the context requires otherwise.

### DETAILED DESCRIPTION

The present invention encompasses circuits and methods for providing a protection circuit that provides improved protection of DC-biased IC terminals, particularly for LNAs lacking a DC blocking input capacitor (“capless LNAs”). Novel circuitry provides circuit protection against large signals and is comparable in performance to an anti-parallel diode voltage clamp for a non-DC biased IC input.

More particularly, the novel protection circuitry makes use of a series-diode protection circuit but adds a two-state circuit. For small signals at an IC terminal, the two-state circuit keeps the series diodes of the series-diode protection circuit reverse-biased. However, for high voltage swings at an IC terminal, the two-state circuit couples the inputs to the series-diode protection circuit so that the diodes behave like anti-parallel diodes despite the presence of a DC bias on the IC input. The added two-state circuit has a minimal impact on circuit performance (e.g., noise-figure or gain for an LNA).

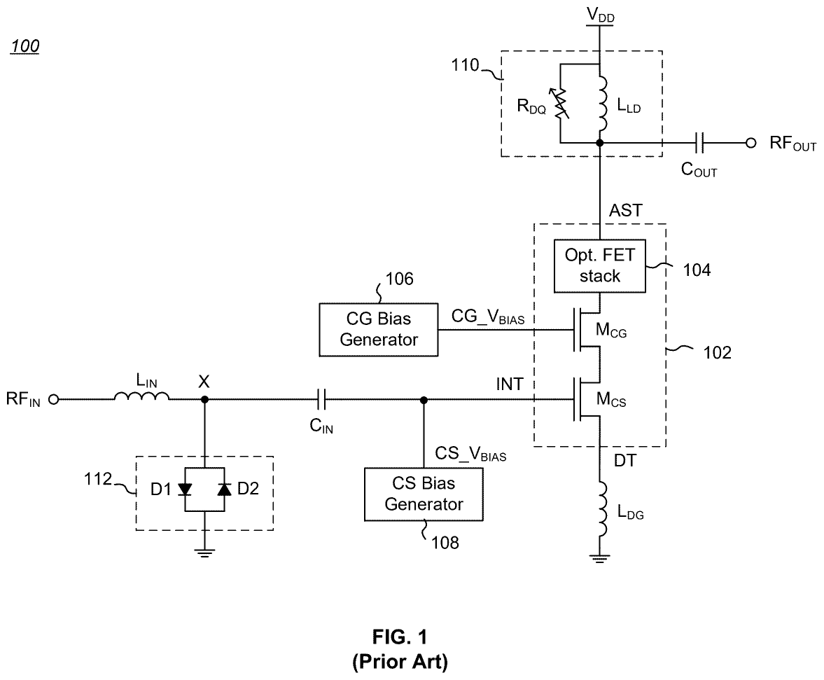

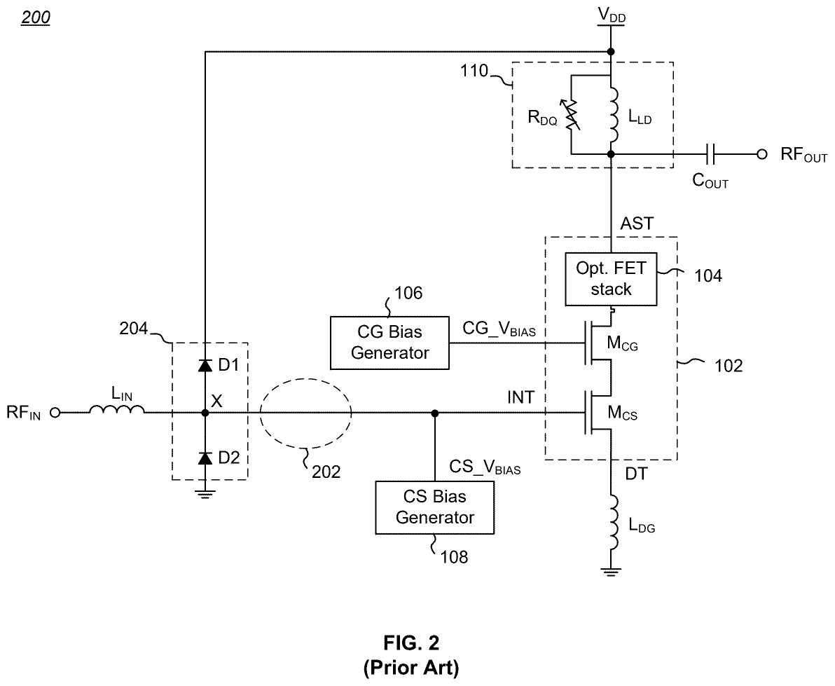

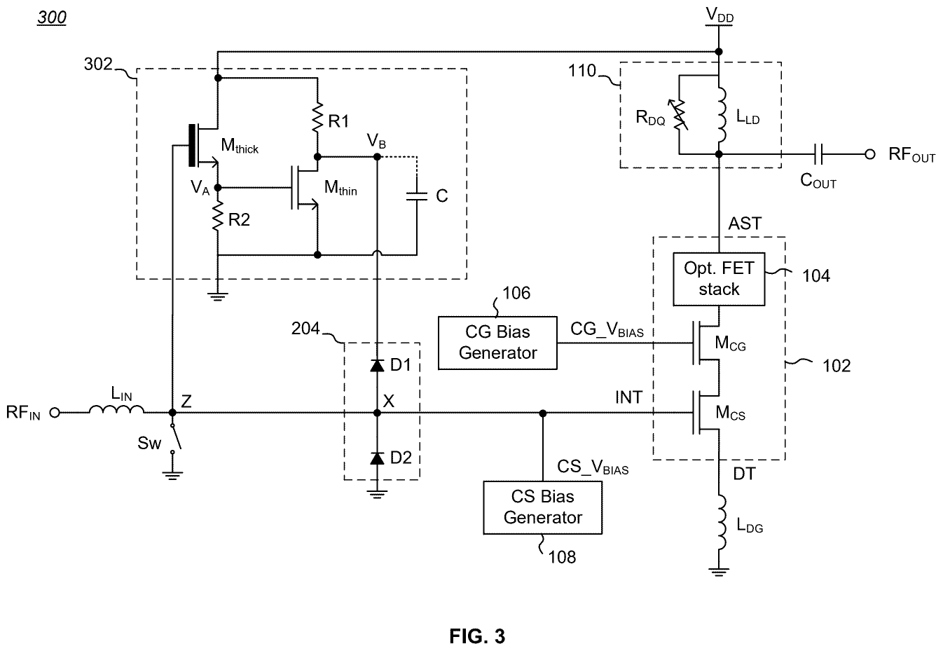

FIG. 3 is a simplified schematic diagram of an example LNA circuit 300 with improved protection circuitry in accordance with the present invention. The novel LNA circuit 300 is similar in many aspects to LNA 100 and LNA 200 of FIG. 1 and FIG. 2, respectively. However, the novel LNA circuit 300 includes a two-state circuit 302 that is coupled (1) to diode D1 of the series-diode protection circuit 204, (2) to the signal path at a node Z at the junction of the input terminal RF_{IN}, the input port INT of the amplification core 102, and the reference potential, and (3) to V_{DD}.

The two-state circuit 302 includes a thick-oxide FET M_{thick} having its gate coupled to node Z and its conduction channel (between drain and source) coupled between V_{DD} and a resistor R2. Resistor R2 is also coupled to a reference potential (which in this example is circuit ground). A node V_{A} between the source of FET M_{thick} and resistor R2 is coupled to the gate of a thin-oxide (relative to FET M_{thick}) FET Mₜₕᵢₙ. The conduction channel of FET Mₜₕᵢₙ is coupled between a resistor R1 and the reference potential. Resistor R1 is also coupled to V_{DD}. The cathode of diode D1 within the series-diode protection circuit 204 is coupled to a node V_{B} coupled between the drain of FET Mₜₕᵢₙ and resistor R1. In some embodiments, a capacitor C may be coupled between node V_{B} and the reference potential.

FET M_{thick} acts like a half-wave rectifier, generating current pulses every time the IC terminal goes above the threshold voltage V_{TH} of FET M_{thick}. The voltage at node V_{A} includes charge from such current pulses plus a DC voltage from charging of the capacitance associated with the gate of FET Mₜₕᵢₙ. Stated another way, the voltage at node V_{A} is a combination of the RF_{IN}-controlled ON/OFF state of FET M_{thick} and the capacitance associated with the gate of FET Mₜₕᵢₙ. The RF swing at the IC terminal is distributed between the gate-source capacitance C_{GS} of FET M_{thick} and the gate capacitance of FET Mₜₕᵢₙ.

The voltage at node V_{A} controls the ON/OFF state of FET Mₜₕᵢₙ. In the illustrated embodiment, FET Mₜₕᵢₙ is turned ON once V_{A} is above the threshold voltage V_{TH} of the device and thus starts conducting, pulling node V_{B} to circuit ground (ideally with low impedance). During high-voltage RF swings at an IC terminal (e.g., at the input terminal RF_{IN} of the LNA 300), FET Mₜₕᵢₙ should be turned ON, pulling node V_{B} down to circuit ground. Accordingly, the series-diode protection circuit 204 is effectively reconfigured to be an anti-parallel diode voltage clamp. Due to DC current passing through diode D1, generated by half-wave rectifying operation of D1 during high-voltage swings at the IC terminal, the gate of the common-source FET M_{CS} is pulled closer to circuit ground due to a voltage drop across a resistance provided by the CS Bias Generator 108.

Conversely, when small signals are present at the IC terminal, FET Mₜₕᵢₙ should be OFF and node V_{B} is pulled up to V_{DD} through resistor R1. Accordingly, the series-diode protection circuit 204 behaves the same way as the series-diode protection circuit 204 of FIG. 2.

Optional capacitor C is included in some embodiments, and may be added to avoid a sudden increase in drain potential of FET Mₜₕᵢₙ in case of an electro-static discharge (ESD) event occurring at the IC terminal. Capacitor C, if present, also lowers RF ripple through FET Mₜₕᵢₙ when in an ON state.

The thick-oxide FET M_{thick} preferably has a higher breakdown voltage than the thin-oxide FET Mₜₕᵢₙ, and thus can better withstand a higher-voltage input signal than FET Mₜₕᵢₙ. Preferably, the device size of FET M_{thick} should be small enough so that its impact on RF performance is minimal, but at the same time the device size should be big enough to generate enough current pulses to quickly charge node V_{A} to above the threshold voltage V_{TH} of FET Mₜₕᵢₙ (note that the DC voltage of V_{A} cannot exceed V_{DD}).

The thin-oxide FET Mₜₕᵢₙ should be large so that its ON-resistance, R_{ON}, is low. Resistor R1 should be very large (e.g., about 8 kΩ) compared to the R_{ON} of FET Mₜₕᵢₙ. Resistor R2 helps in setting the DC voltage for node V_{A}, and the larger the resistance value, the greater would be the DC voltage at node V_{A}. In addition, the upper value of resistor R2 will set the “turn on time constant” when an alternating RF is applied to the IC terminal—if resistor R2 is too large, damage may occur before the two-state circuit 302 engages. A useful value for resistor R2 in some example embodiments has been about 200 kΩ. The size of capacitor C, if used for ESD, should be large enough to protect the IC terminal during an ESD event.

FIG. 3 also includes a shunt switch S_{W} connected between node Z and the reference potential. Because diode D1 has resistor R1 in series to V_{DD}, current from an ESD event may not take this path, leading to potential failure. Accordingly, it may be useful to configure the shunt switch S_{W} as a self-biased switch which can turn ON during an ESD event. One example of a self-activating limiter is described in U.S. Pat. No. 8,928,388, entitled “Self-Activating Adjustable Power Limiter”, issued assigned to the assignee of the present invention, which is hereby incorporated by reference.

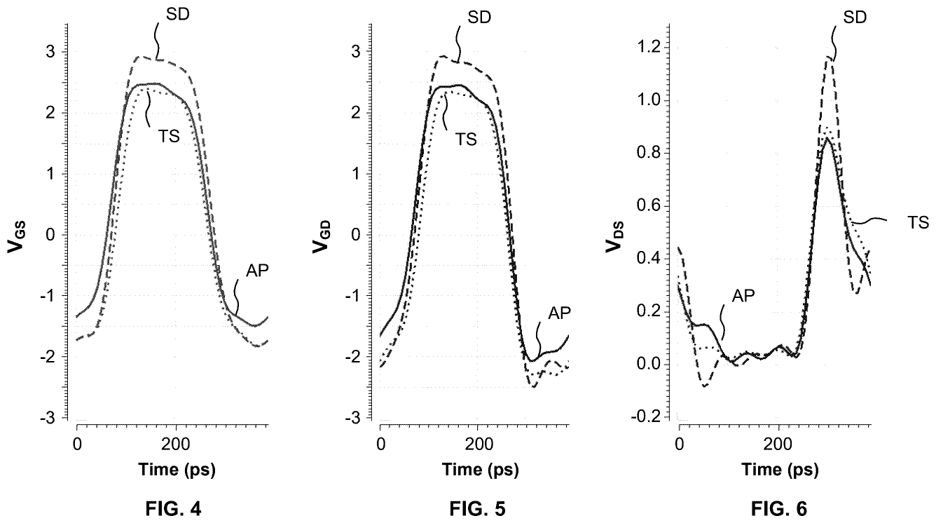

FIGS. 4-6 are graphs of voltages versus time for the V_{GS}, V_{GD}, and V_{DS} parameters, respectively, of the common-source FET M_{CS} of an LNA during a large signal event, for three different protection circuits.

The solid graph line AP in each figure represents the behavior of an LNA having no input DC bias and which utilizes a voltage clamp comprising anti-parallel coupled diodes (as in FIG. 1).

The dashed graph line SD in each figure represents the behavior of an LNA having an input DC bias and which utilizes a series-diode protection circuit (as in FIG. 2).

The dotted graph line TS in each figure represents the behavior of an LNA having an input DC bias and which utilizes a series-diode protection circuit and a two-state circuit (as in FIG. 3).

A first parameter, Vmax, may be defined as the maximum voltage for any of V_{GS}, V_{GD}, and V_{DS}. A second parameter, Vmin, may be defined as the minimum voltage for any of V_{GS}, V_{GD}, and V_{DS}. With a large signal input, the behavior of anti-parallel coupled diodes (solid graph lines AP) is better than the behavior of series-diodes (dashed graph lines SD), but of course anti-parallel coupled diodes cannot be used in circuits having an input DC bias (such as a capless LNA). However, in a circuit having an input DC bias, the voltage swing Vmax during an entire cycle for the combination of a series-diode protection circuit and a two-state circuit in accordance with the present invention is either similar or lower than the Vmax for anti-parallel coupled diodes, as shown by comparing dotted graph lines TS to solid graph lines AP.

The LNA circuit 300 of FIG. 3 is a basic LNA architecture. As will be appreciated by one of ordinary skill in the art, a number of variant LNAs may beneficially include the protective circuitry of the present invention. For example, additional control and configuration switches may be included, and the LNA circuit 300 may include more than one amplifier core 102. Additional circuitry may include (1) an output clamp coupled between the output terminal RF_{OUT} and the reference potential to clamp transient signals, (2) a filter capacitor C_{F} coupled between the voltage source terminal V_{DD} and the reference potential to filter noise that may be present at that node, and (3) a clamp diode coupled between the voltage source terminal V_{DD} and the amplified-signal port AST to reduce the voltage swing at the LNA output, which will benefits parameter specifications (e.g., output saturation power) that are required in many applications. In some variants, the bias voltages CG_V_{BIAS} and CS_V_{BIAS} may be variable, the degeneration inductor L_{DG} may be variable and/or bypassable, the load module 110 may include additional and/or more complex (e.g., variable and/or bypassable) LRC components, and feedback circuitry may be coupled between the amplified-signal port AST and the input port INT. Configuration switches may be used to selectively connect or disconnect various circuit elements, for example, to accommodate different gain modes of operation.

While the example circuit shown in FIG. 3 is an LNA, the invention may be used for any circuit block (e.g., mixers, power amplifiers, RF switches) that needs to limit voltage swing on either its input or output terminals. Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

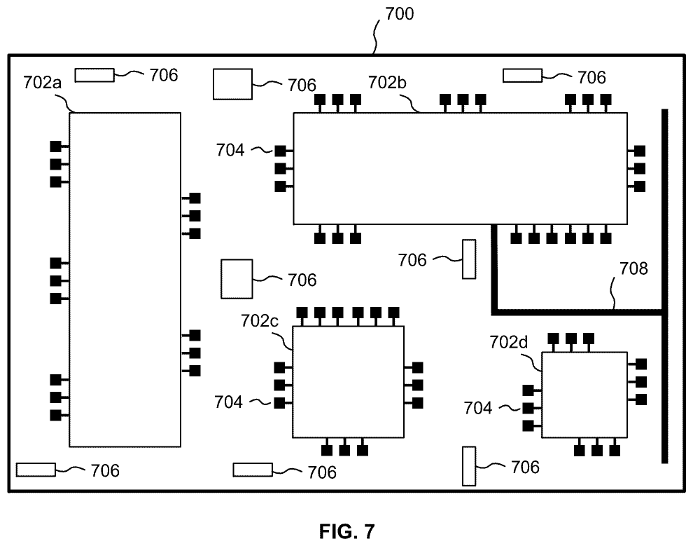

As one example of further integration of embodiments of the present invention with other components, FIG. 7 is a top plan view of a substrate 700 that may be, for example, a printed circuit board or chip module substrate (e.g., a thin-film tile). In the illustrated example, the substrate 700 includes multiple ICs 702a-702d having terminal pads 704 which would be interconnected by conductive vias and/or traces on and/or within the substrate 700 or on the opposite (back) surface of the substrate 700 (to avoid clutter, the surface conductive traces are not shown and not all terminal pads are labelled). The ICs 702a-702d may embody, for example, signal switches, active and/or passive filters, amplifiers (including one or more LNAs), and other circuitry. For example, IC 702b may incorporate one or more instances of an LNA like the LNA 300 shown in FIG. 3.

The substrate 700 may also include one or more passive devices 706 embedded in, formed on, and/or affixed to the substrate 700. While shown as generic rectangles, the passive devices 706 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 700 to other passive devices 706 and/or the individual ICs 702a-702d.

The front or back surface of the substrate 700 may be used as a location for the formation of other structures. For example, one or more antennae may be formed on or affixed to the front or back surface of the substrate 700; one example of a front-surface antenna 708 is shown, coupled to an IC die 702b, which may include RF front-end circuitry. Thus, by including one or more antennae on the substrate 700, a complete radio may be created.

Embodiments of the present invention are useful in a wide variety of larger radio frequency (RF) circuits and systems for performing a range of functions, including (but not limited to) impedance matching circuits, RF power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

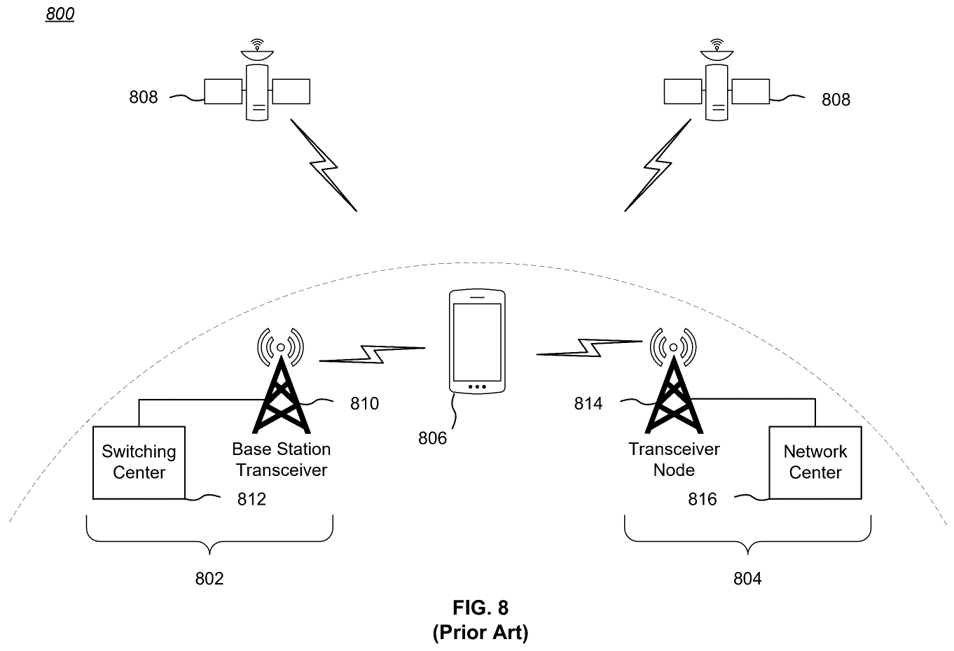

As an example of wireless RF system usage, FIG. 8 illustrates a prior art wireless communication environment 800 comprising different wireless communication systems 802 and 804, and which may include one or more mobile wireless devices 806. A wireless device 806 may be a cellular phone, a wireless-enabled computer or tablet, or some other wireless communication unit or device. A wireless device 806 may also be referred to as a mobile station, user equipment, an access terminal, or some other terminology known in the telecommunications industry.

A wireless device 806 may be capable of communicating with multiple wireless communication systems 802, 804 using one or more of telecommunication protocols such as the protocols noted above. A wireless device 806 also may be capable of communicating with one or more satellites 808, such as navigation satellites (e.g., GPS) and/or telecommunication satellites. The wireless device 806 may be equipped with multiple antennas, externally and/or internally, for operation on different frequencies and/or to provide diversity against deleterious path effects such as fading and multi-path interference.

The wireless communication system 802 may be, for example, a CDMA-based system that includes one or more base station transceivers (BSTs) 810 and at least one switching center (SC) 812. Each BST 810 provides over-the-air RF communication for wireless devices 806 within its coverage area. The SC 812 couples to one or more BSTs 810 in the wireless system 802 and provides coordination and control for those BSTs 810.

The wireless communication system 804 may be, for example, a TDMA-based system that includes one or more transceiver nodes 814 and a network center (NC) 816. Each transceiver node 814 provides over-the-air RF communication for wireless devices 806 within its coverage area. The NC 816 couples to one or more transceiver nodes 814 in the wireless system 804 and provides coordination and control for those transceiver nodes 814.

In general, each BST 810 and transceiver node 814 is a fixed station that provides communication coverage for wireless devices 806, and may also be referred to as base stations or some other terminology known in the telecommunications industry. The SC 812 and the NC 816 are network entities that provide coordination and control for the base stations and may also be referred to by other terminologies known in the telecommunications industry.

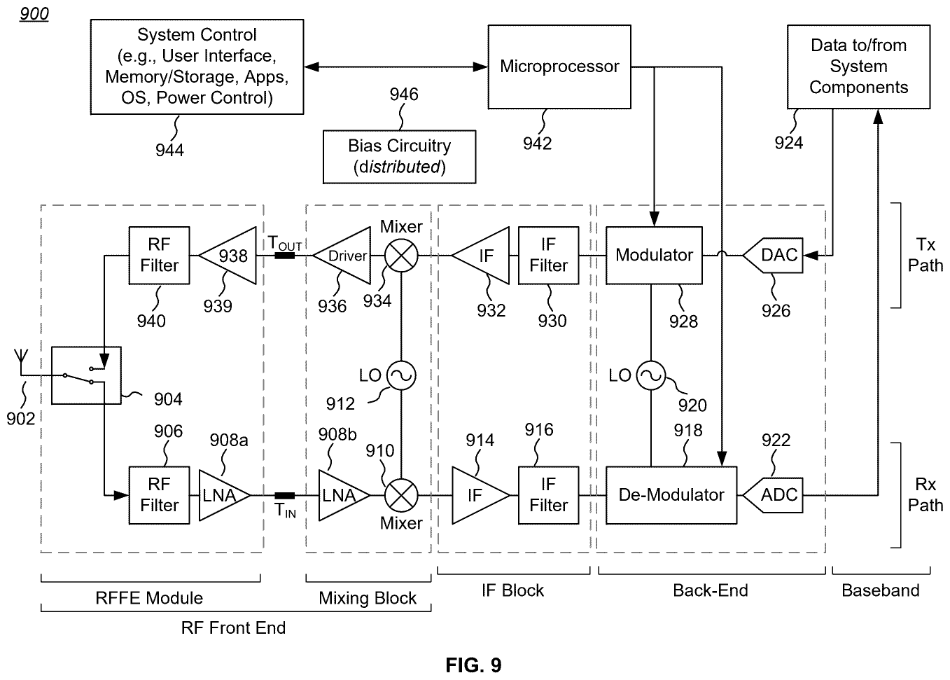

An important aspect of any wireless system, including the systems shown in FIG. 9, is in the details of how the component elements of the system perform. FIG. 9 is a block diagram of a transceiver 900 that might be used in a wireless device, such as a cellular telephone, and which may beneficially incorporate an embodiment of the present invention for improved performance. As illustrated, the transceiver 900 includes a mix of RF analog circuitry for directly conveying and/or transforming signals on an RF signal path, non-RF analog circuity for operational needs outside of the RF signal path (e.g., for bias voltages and switching signals), and digital circuitry for control and user interface requirements. In this example, a receiver path Rx includes RF Front End (RFFE), Intermediate Frequency (IF) Block, Back-End, and Baseband sections (noting that in some implementations, the differentiation between sections may be different). The various illustrated sections and circuit elements may be embodied in one die or multiple IC dies. For example, the RF Front End in the illustrated example may include an RFFE module and a Mixing Block, which may be embodied in (or as part of) different IC dies or modules. The different dies and/or modules may be coupled by transmission lines T_{IN} and T_{OUT} (e.g., microstrips, co-planar waveguides, or an equivalent structure or circuit), either or both of which may have, for example, a 50 Ω impedance.

The receiver path Rx receives over-the-air RF signals through at least one antenna 902 and a switching unit 904, which may be implemented with active switching devices (e.g., field effect transistors or FETs) and/or with passive devices that implement frequency-domain multiplexing, such as a diplexer or duplexer. An RF filter 906 passes desired received RF signals to at least one low noise amplifier (LNA) 908a, the output of which is coupled from the RFFE Module to at least one LNA 908b in the Mixing Block (through transmission line T_{IN} in this example). The LNA(s) 908b may provide buffering, input matching, and reverse isolation. In some embodiments, the LNA(s) 908a and 908b may be a single LNA. The LNA(s) 908a and 908b may include protection circuitry in accordance with the present invention.

The output of the LNA(s) 908b is combined in a corresponding mixer 910 with the output of a first local oscillator 912 to produce an IF signal. The IF signal may be amplified by an IF amplifier 914 and subjected to an IF filter 916 before being applied to a demodulator 918, which may be coupled to a second local oscillator 920. The demodulated output of the demodulator 918 is transformed to a digital signal by an analog-to-digital converter 922 and provided to one or more system components 924 (e.g., a video graphics circuit, a sound circuit, memory devices, etc.). The converted digital signal may represent, for example, video or still images, sounds, or symbols, such as text or other characters.

In the illustrated example, a transmitter path Tx includes Baseband, Back-End, IF Block, and RF Front End sections (again, in some implementations, the differentiation between sections may be different). Digital data from one or more system components 924 is transformed to an analog signal by a digital-to-analog converter 926, the output of which is applied to a modulator 928, which also may be coupled to the second local oscillator 920. The modulated output of the modulator 928 may be subjected to an IF filter 930 before being amplified by an IF amplifier 932. The output of the IF amplifier 932 is then combined in a mixer 934 with the output of the first local oscillator 912 to produce an RF signal. The RF signal may be amplified by a driver 936, the output of which is coupled to a power amplifier (PA) 938 (through transmission line T_{OUT} in this example). The amplified RF signal may be coupled to an RF filter 940, the output of which is coupled to at least one antenna 902 through the switching unit 904.

The operation of the transceiver 900 is controlled by a microprocessor 942 in known fashion, which interacts with system control components 944 (e.g., user interfaces, memory/storage devices, application programs, operating system software, power control, etc.). In addition, the transceiver 900 will generally include other circuitry, such as bias circuitry 946 (which may be distributed throughout the transceiver 900 in proximity to transistor devices), electro-static discharge (ESD) protection circuits, testing circuits (not shown), factory programming interfaces (not shown), etc.

In modern transceivers, there are often more than one receiver path Rx and transmitter path Tx, for example, to accommodate multiple frequencies and/or signaling modalities. Further, as should be apparent to one of ordinary skill in the art, some components of the transceiver 900 may be positioned in a different order (e.g., filters) or omitted. Other components can be (and often are) added, such as (by way of example only) additional filters, impedance matching networks, variable phase shifters/attenuators, power dividers, etc.

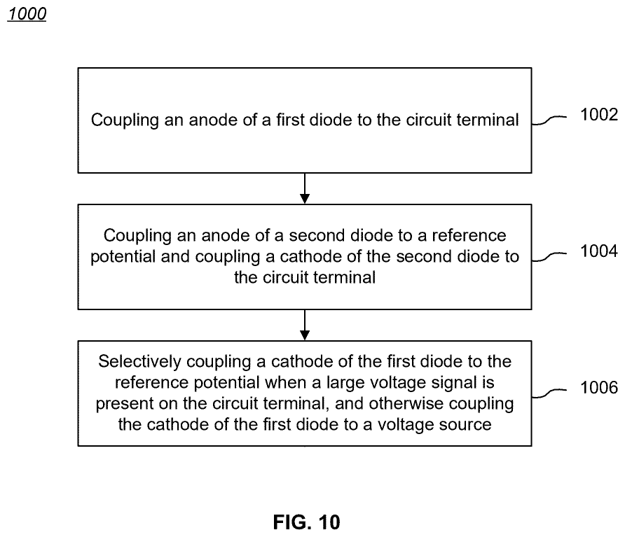

Another aspect of the invention includes corresponding methods for protecting circuit terminals. For example, FIG. 10 is a process flow chart 1000 showing one method of protecting a circuit terminal. The method includes: coupling an anode of a first diode to the circuit terminal (BLOCK 1002); coupling an anode of a second diode to a reference potential and coupling a cathode of the second diode to the circuit terminal (BLOCK 1004); and selectively coupling a cathode of the first diode to the reference potential when a large voltage signal is present on the circuit terminal, and otherwise coupling the cathode of the first diode to a voltage source (BLOCK 1006).

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as bipolar junction transistors (BJTs), BiCMOS, LDMOS, BCD, GaAs HBT, GaN HEMT, GaAs pHEMT, MESFET, InP HBT, InP HEMT, FinFET, GAAFET, and SiC-based device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

### Conclusion

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. A protection circuit configured to be coupled to a circuit terminal and including:
(a) a two-state circuit configured to be coupled to the circuit terminal, a voltage source, and a reference potential, the two-state circuit including a first node selectably couplable to the voltage source or to the reference potential; and
(b) a series-diode protection circuit configured to be coupled to the circuit terminal, the reference potential, and the first node of the two-state circuit.

2. The protection circuit of claim 1, wherein the two-state circuit selectively couples the first node to the reference potential when a large voltage signal is present on the circuit terminal, and otherwise couples the first node to the voltage source.

3. The protection circuit of claim 1, wherein the two-state circuit includes:
(a) a first FET having a gate and having a conduction channel configured to be coupled to the reference potential;
(b) a first resistor coupled to the conduction channel of the first FET and configured to be coupled to the voltage source;
(c) a second FET having a gate configured to be coupled to the circuit terminal and a conduction channel configured to be coupled to the voltage source;
(d) a second resistor coupled to the conduction channel of the second FET and configured to be coupled to the reference potential;
wherein the first node is located between the first resistor and the conduction channel of the first FET; and
wherein the gate of the first FET is coupled to a second node between the second resistor and the conduction channel of the second FET.

4. The protection circuit of claim 3, wherein the first FET is a thin-oxide FET and the second FET is a thick-oxide FET having a higher breakdown voltage than the thin-oxide first FET.

5. The protection circuit of claim 1, further including a capacitor coupled to the first node and configured to be coupled to the reference potential.

6. The protection circuit of claim 1, wherein the series-diode protection circuit includes:
(a) a first diode having an anode configured to be coupled to the circuit terminal and a cathode coupled to the first node; and
(b) a second diode having an anode configured to be coupled to the reference potential and a cathode configured to be coupled to the circuit terminal.

7. A circuit including:
(a) an input terminal configured to receive an input signal;
(b) an output terminal configured to conduct an output signal as a function of the input signal;
(c) a voltage source terminal configured to be coupled to a voltage source;
(d) a two-state circuit coupled to the input terminal, the voltage source terminal, and a reference potential, the two-state circuit including a first node selectably couplable to the voltage source terminal or to the reference potential; and
(e) a series-diode protection circuit coupled to the input terminal, the reference potential, and the first node of the two-state circuit.

8. The circuit of claim 7, wherein the two-state circuit selectively couples the first node to the reference potential when a large voltage signal is present on the input terminal, and otherwise couples the first node to the voltage source terminal.

9. The circuit of claim 7, wherein the two-state circuit includes:
(a) a first FET having a gate and having a conduction channel coupled to the reference potential;
(b) a first resistor coupled between the conduction channel of the first FET and the voltage source terminal;
(c) a second FET having a gate coupled to the input terminal and a conduction channel coupled to the voltage source terminal;
(d) a second resistor coupled between the conduction channel of the second FET and the reference potential;
wherein the first node is located between the first resistor and the conduction channel of the first FET; and
wherein the gate of the first FET is coupled to a second node between the second resistor and the conduction channel of the second FET.

10. The circuit of claim 9, wherein the first FET is a thin-oxide FET and the second FET is a thick-oxide FET having a higher breakdown voltage than the thin-oxide first FET.

11. The circuit of claim 7, further including a capacitor coupled between the first node and the reference potential.

12. The circuit of claim 7, wherein the series-diode protection circuit includes:
(a) a first diode having an anode coupled to the input terminal and a cathode coupled to the first node; and
(b) a second diode having an anode coupled to the reference potential and a cathode coupled to the input terminal.

13. The circuit of claim 7, further including a self-biased switch coupled between the input terminal and the reference potential.

14. The circuit of claim 7, wherein the circuit is a low-noise amplifier and the output signal is an amplified version of the input signal.

15. A low-noise amplifier circuit including:
(a) an input terminal configured to receive an input signal;
(b) an output terminal configured to output an amplified version of the input signal;
(c) a voltage source terminal configured to be coupled to a voltage source;
(d) a series-diode protection circuit coupled to the input terminal and a reference potential, the series-diode protection circuit including:
(1) a first diode having an anode coupled to the input terminal and having a cathode; and
(2) a second diode having an anode coupled to the reference potential and having a cathode coupled to the input terminal;
(e) a two-state circuit coupled to the input terminal, the voltage source terminal, the reference potential, and the series-diode protection circuit, the two-state circuit including:
(1) a first FET having a gate and having a conduction channel coupled to the reference potential;
(2) a first resistor coupled between the conduction channel of the first FET and the voltage source terminal;
(3) a second FET having a gate coupled to the input terminal and having a conduction channel coupled to the voltage source terminal;
(4) a second resistor coupled between the conduction channel of the second FET and the reference potential;
(5) a first node located between the first resistor and the conduction channel of the first FET and coupled to the cathode of the first diode of the series-diode protection circuit, wherein the first node is selectably couplable to the voltage source terminal or to the reference potential; and
(6) a second node located between the second resistor and the conduction channel of the second FET, wherein the second node is coupled to the gate of the first FET.

16. The low-noise amplifier circuit of claim 15, wherein the two-state circuit selectively couples the first node to the reference potential when a large voltage signal is present on the circuit terminal, and otherwise couples the first node to the voltage source.

17. The protection circuit of claim 15, wherein the first FET is a thin-oxide FET and the second FET is a thick-oxide FET having a higher breakdown voltage than the thin-oxide first FET.

18. The protection circuit of claim 15, further including a capacitor coupled between the first node and the reference potential.

19. The circuit of claim 15, further including a self-biased switch coupled between the input terminal and the reference potential.

20. A method of protecting a circuit terminal, including:
(a) coupling an anode of a first diode to the circuit terminal;
(b) coupling an anode of a second diode to a reference potential and coupling a cathode of the second diode to the circuit terminal; and
(c) selectively coupling a cathode of the first diode to the reference potential when a large voltage signal is present on the circuit terminal, and otherwise coupling the cathode of the first diode to a voltage source.
